(19) United States
(12) Patent Application Publication
(10) Pub. No.: US 2026/0259506 A1
(43) Pub. Date: Sep. 3, 2026

(54) MEASUREMENT APPARATUS, POSITIONING APPARATUS, LITHOGRAPHY APPARATUS, AND ARTICLE MANUFACTURING METHOD

(71) Applicant: CANON KABUSHIKI KAISHA, Tokyo (JP)

(72) Inventors: YUSUKE ENDO, Tochigi (JP); SHIGEO KOYA, Tochigi (JP); NAOKI FUNABASHI, Tochigi (JP)

(21) Appl. No.: 19/546,865

(22) Filed: Feb. 23, 2026

(30) Foreign Application Priority Data
Feb. 28, 2025 (JP) 2025-031940

(51) Int. Cl. G03F 7/00

(52) U.S. Cl. CPC G03F 7/70516; G03F 7/70725

(57) ABSTRACT

The present disclosure provides A measurement apparatus that measures a position of a measurement target surface, comprising: a sensor including a facing portion which faces the measurement target surface, and configured to measure a position of the measurement target surface in a first state in which the facing portion is arranged at a predetermined spacing from the measurement target surface; and a moving unit configured to move at least the facing portion of the sensor, wherein the moving unit operates in a first mode for moving the facing portion in a direction away from the measurement target surface in accordance with reception of a first signal, and a second mode for moving the facing portion in the direction in accordance with reception of a second signal.

### BACKGROUND

### Field of the Technology

The present disclosure relates to a measurement apparatus, a positioning apparatus, a lithography apparatus, and an article manufacturing method.

### Description of the Related Art

Japanese Patent Laid-Open No. 2006-189429 describes an air sensor (gas measurement proximity sensor) that arranges a measurement probe, which sprays a gas through a conduit, close to a measurement surface (measurement target surface) and measures the position of the measurement surface based on the pressure in the conduit. In the air sensor described in Japanese Patent Laid-Open No. 2006-189429, in order to avoid collision between the measurement probe and the measurement surface, the separation distance between the measurement probe and the measurement surface is controlled to be constant.

As for a sensor such as the air sensor that includes a portion which is arranged close to a measurement target surface during measurement of the position of the measurement target surface, in order to avoid contact between the air sensor and the measurement target surface, when measurement of the position of the measurement target surface ends, the sensor is retracted so that the portion is away from the measurement target surface. On the other hand, in an emergency such as when an abnormality (for example, vibration) occurs in the relative position between the sensor and the measurement target surface, the retraction operation at the end of measurement may not be able to retract the air sensor in time, and the air sensor may contact the measurement target surface.

### SUMMARY

The present disclosure provides a technique advantageous for appropriately retracting a sensor that measures the position of a measurement target surface.

According to one aspect of the present disclosure, there is provided a measurement apparatus that measures a position of a measurement target surface, comprising: a sensor including a facing portion which faces the measurement target surface, and configured to measure a position of the measurement target surface in a first state in which the facing portion is arranged at a predetermined spacing from the measurement target surface; and a moving unit configured to move at least the facing portion of the sensor, wherein the moving unit operates in a first mode for moving the facing portion in a direction away from the measurement target surface in accordance with reception of a first signal instructing to retract the facing portion when measurement by the sensor ends, and a second mode for moving the facing portion in the direction in accordance with reception of a second signal instructing to retract the facing portion in an emergency, and wherein a time from reception of the second signal to an end of retraction of the facing portion in the second mode is shorter than a time from reception of the first signal to an end of retraction of the facing portion in the first mode.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing an example of the configuration of an exposure apparatus according to the first embodiment;

FIG. 2A is a view schematically showing the first configuration example of an air sensor;

FIG. 2B is a view schematically showing the second configuration example of the air sensor;

FIG. 3 is a view schematically showing an example of the configuration of measurement apparatus according to the first embodiment;

FIG. 4 is a flowchart illustrating the operation of the measurement apparatus according to the first embodiment;

FIGS. 5A and 5B are graphs each showing an example of the temporal change of the moving speed of the air sensor in each of the first mode and the second mode;

FIG. 6 is a view schematically showing an example of the configuration of measurement apparatus according to the second embodiment;

FIGS. 7A to 7F are views schematically showing an example of the configuration and operation of the measurement apparatus according to the second embodiment; and

FIG. 8 is a view schematically showing an example of the configuration of measurement apparatus according to the third embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

A lithography apparatus according to the present disclosure is an apparatus that forms a pattern on a substrate. Examples of the lithography apparatus are an exposure apparatus that exposes a substrate to transfer the pattern of an original (mask) to the substrate, and an imprint apparatus that forms a pattern in an imprint material on a substrate by using an original (mold). In the following description, the exposure apparatus will be exemplarily described as the lithography apparatus.

### First Embodiment

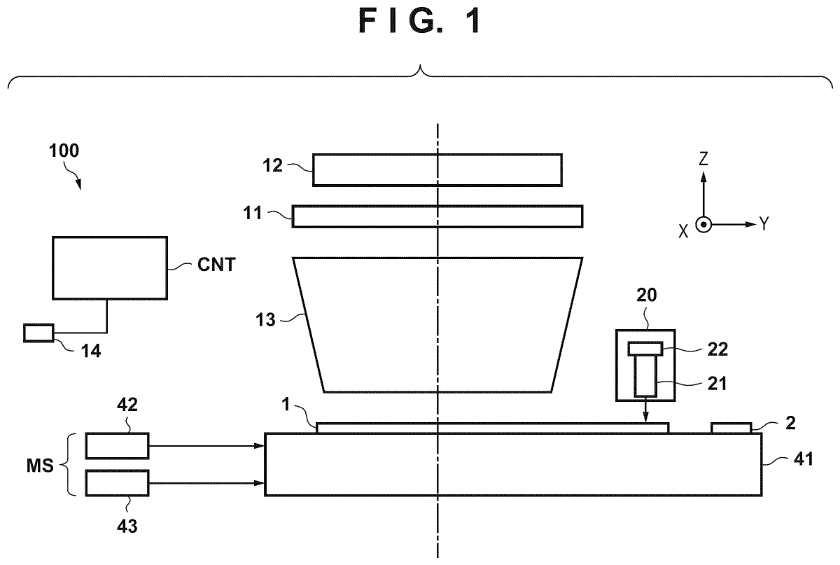

The first embodiment according to the present disclosure will be described. FIG. 1 schematically shows an example of the configuration of an exposure apparatus 100 according to this embodiment. The exposure apparatus 100 includes an illumination optical system 12 that illuminates an original 11, and a projection optical system 13 that projects the pattern of the original 11 onto a substrate 1, and can be configured to project the pattern of the original 11 onto the substrate 1 by the projection optical system 13 and expose the substrate 1. The exposure apparatus 100 can also include a substrate stage 41 that can move while holding the substrate 1, a measurement apparatus 20 that measures the position (height) of a measurement target surface, and a controller CNT. The measurement apparatus 20 according to this embodiment can be configured to measure the surface height (surface position) of the substrate 1 as the position of a measurement target surface. The substrate stage 41, the measurement apparatus 20, and the controller CNT in the exposure apparatus 100 according to this embodiment can constitute a positioning apparatus that positions the substrate 1. In the positioning apparatus, the controller CNT controls the substrate stage 41 based on the measurement result of the measurement apparatus 20.

The substrate stage 41 holds the substrate 1, and drives the substrate 1 in the X and Y directions by moving on a stage base (not shown) in the X and Y directions. The substrate stage 41 may be configured to drive the substrate 1 not only in the X and Y directions but in the directions of six axes (X, Y, Z, θX, θY, and θZ). A reference plate 2 having a reference surface can be provided on the substrate stage 41. The reference surface of the reference plate 2 is a flat surface, and the reference surface can be provided with, for example, a reference mark whose position is detected by an alignment sensor (not shown).

The position and posture of the substrate stage 41 can be measured by a position measurement system MS, and controlled by the controller CNT based on the output of the position measurement system MS. The position measurement system MS includes a plurality of position measuring devices, and measures the position and posture of the substrate stage 41 about six axes (X, Y, Z, θX, θY, and θZ). In FIG. 1, two position measuring devices 42 and 43 for measuring the Y-direction position of the substrate stage 41 are shown. However, in practice, a position measuring device for measuring the X-direction position of the substrate stage 41, a position measuring device for measuring the Z-direction position of the substrate stage 41, and the like are also provided. Each position measuring device may include, for example, an interferometer, an encoder, or one or more interferometers and one or more encoders.

The measurement apparatus 20 includes an air sensor 21, and measures the surface height of the substrate 1 by using the air sensor 21. The air sensor 21 is a sensor (measuring device) that discharges (sprays) air (gas) toward the surface of the substrate 1 through a conduit, and measures the surface height of the substrate 1 based on the pressure in the conduit. Since the air discharged from the air sensor 21 only hits the outermost surface of the substrate 1 and does not enter the interior of the substrate 1, the air sensor 21 can accurately measure the surface height of the substrate 1 without being influenced by the internal structure of the substrate 1. For example, the air sensor 21 can be configured to be capable of measuring the surface height of the substrate 1 with a resolution on the order of nanometers or higher than 1 nm. Note that the air sensor 21 is sometimes called an air gauge sensor, an air gap sensor, or an air micro sensor.

The controller CNT is constituted by, for example, a computer (information processing apparatus) including a processor such as a Central Processing Unit (CPU) and a storage unit such as a memory, and controls respective units of the exposure apparatus 100. The controller CNT may be implemented by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer with a program installed therein, or a combination of all or some of these.

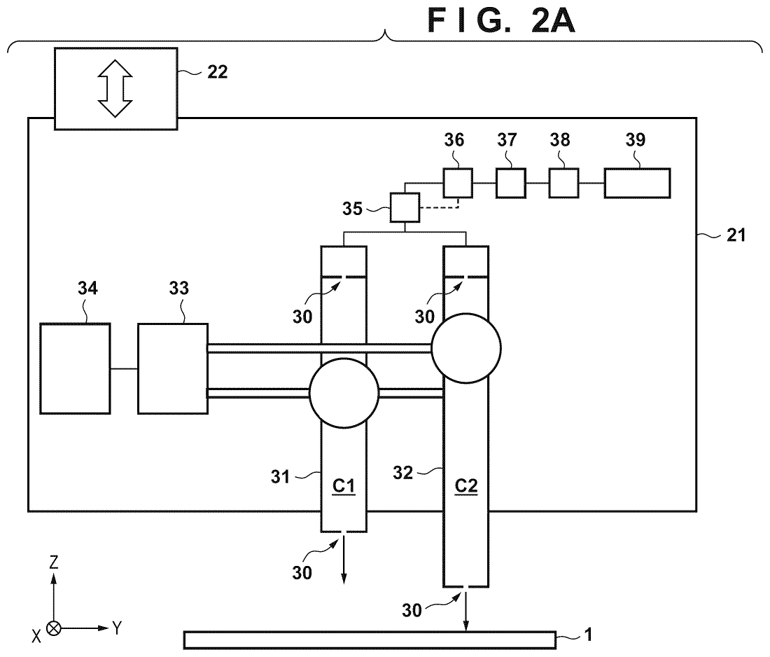

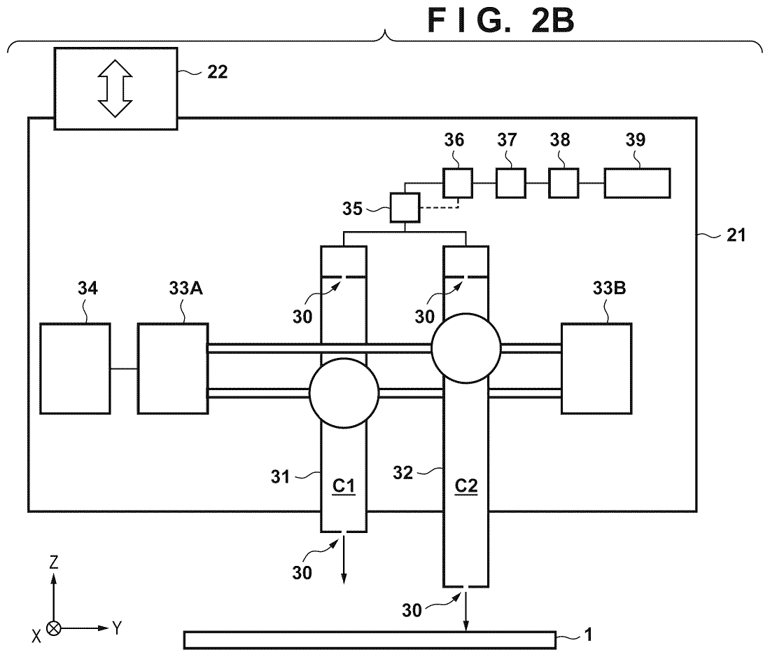

Next, an example of the configuration of the air sensor 21 will be described. FIG. 2A schematically shows the first configuration example of the air sensor 21. The air sensor 21 can include a reference nozzle 31 that discharges air through a first conduit C1, a measurement nozzle 32 that discharges air through a second conduit C2, and a differential pressure sensor 33 that detects the difference between the pressure in the first conduit C1 and the pressure in the second conduit C2. In each of the reference nozzle 31 and the measurement nozzle 32, orifices 30 are provided at the air inlet and outlet.

Air can be supplied to the reference nozzle 31 (first conduit C1) and the measurement nozzle 32 (second conduit C2) from a mass flow controller 36 via a sensor 35 such as a pressure gauge or a flowmeter. Air is supplied to the mass flow controller 36 from a gas supply source 39 via a valve 38 and a filter 37. The valve 38 can be provided to turn on/off the air supply from the gas supply source 39 to the mass flow controller 36. The filter 37 can be provided to supply clean air to the mass flow controller 36 from the gas supply source 39. The output of the differential pressure sensor 33 is transmitted to a processor 34, and the processor 34 converts the output of the differential pressure sensor 33 (that is, the difference between the pressure in the first conduit C1 and the pressure in the second conduit C2) into height information.

The mass flow controller 36 supplies, to the reference nozzle 31 and the measurement nozzle 32, air with the pressure and flow rate adjusted to be constant. More specifically, based on the output of the sensor 35, the mass flow controller 36 can operate to keep the pressure at the outlet of the mass flow controller 36 at a predetermined pressure (for example, 70 kPa±0.01 kPa). The diameter of the orifice 30 provided in each of the reference nozzle 31 and the measurement nozzle 32 can be, for example, within a range of 0.1 mm to 0.2 mm. Since the orifice 30 acts as a resistance to the air flow, the pressure in the first conduit C1 of the reference nozzle 31 can be kept constant. On the other hand, the pressure in the second conduit C2 of the measurement nozzle 32 has a value corresponding to the distance between the measurement nozzle 32 and the measurement target surface. That is, the pressure in the second conduit C2 increases as the distance between the measurement nozzle 32 and the measurement target surface decreases, and the pressure in the second conduit C2 decreases as the distance increases. Note that in this embodiment, the measurement target surface is the surface of the substrate 1, but may be the surface of the reference plate 2.

The differential pressure sensor 33 is provided with the pressure in the first conduit C1 of the reference nozzle 31 and the pressure in the second conduit C2 of the measurement nozzle 32. That is, the differential pressure corresponding to the distance between the measurement nozzle 32 and the measurement target surface is supplied to the differential pressure sensor 33. The processor 34 converts the output of the differential pressure sensor 33 into height information of the measurement target surface, and provides the height information to the controller CNT. In this manner, the air sensor 21 measures the height of a measurement target surface by discharging air toward the measurement target surface which is the outermost surface. Therefore, a measurement error caused by the internal structure that can exist below the measurement target surface does not occur.

The air sensor 21 according to this embodiment includes the measurement nozzle 32 as a facing portion which faces the surface of the substrate 1 serving as the measurement target surface, and measures the surface height of the substrate 1 in a state (first state) in which the measurement nozzle 32 is arranged at a predetermined spacing from the surface of the substrate 1. This state may be understood as a state in which the distal end (lower end) of the measurement nozzle 32 is brought close to the surface of the substrate 1, and may be referred to as a “nozzle proximity state” below. That is, the air sensor 21 discharges air from the measurement nozzle 32 toward the surface of the substrate 1 in the nozzle proximity state, and measures the surface height of the substrate 1 based on the internal pressure of the measurement nozzle 32 (that is, the pressure in the second conduit C2) at this time.

The measurement apparatus 20 is also provided with a moving unit (driver) 22 configured to move (drive) the air sensor 21. When starting measurement of the surface height of the substrate 1 by the air sensor 21, the moving unit 22 moves the air sensor 21 in the −Z direction so that the measurement nozzle 32 is arranged at a predetermined spacing from the surface of the substrate 1. On the other hand, when measurement of the surface height of the substrate 1 by the air sensor 21 ends (at the end of measurement), the moving unit 22 retracts the air sensor 21 by moving the air sensor 21 in the +Z direction (the direction away from the surface of the substrate 1). That is, the moving unit 22 can be configured to relatively move the air sensor 21 (measurement nozzle 32) in the ±Z directions with respect to the substrate 1. Note that the moving unit 22 may be understood as a driving unit that drives the air sensor 21 in the ±Z directions.

FIG. 2B schematically shows the second configuration example of the air sensor 21. In the second configuration example, a first differential pressure sensor 33A and a second differential pressure sensor 33B are provided in place of the differential pressure sensor 33 in the first configuration example. The first differential pressure sensor 33A detects the difference between the pressure in the first conduit C1 of the reference nozzle 31 and the pressure in the second conduit C2 of the measurement nozzle 32. Similarly, the second differential pressure sensor 33B detects the difference between the pressure in the first conduit C1 of the reference nozzle 31 and the pressure in the second conduit C2 of the measurement nozzle 32. The first differential pressure sensor 33A and the second differential pressure sensor 33B are different from each other in sensitivity (and measurement range). The processor 34 can convert the output of the first differential pressure sensor 33A into height information, and convert the output of the second differential pressure sensor 33B into height information.

If the internal component of the air sensor 21 is deformed or positionally shifted due to an impact such as a vibration, the measurement accuracy can decrease. Therefore, when retracting the air sensor 21 at the end of measurement by the air sensor 21, it is desirable to move the air sensor 21 such that the air sensor 21 is not subjected to an impact (vibration) which causes the deformation or positional shift of the internal component. On the other hand, in the exposure apparatus 100, for example, if an emergency situation occurs, such as an earthquake, an abnormality in the support member of the measurement apparatus 20 (air sensor 21), or an operational abnormality of the substrate stage 41, the air sensor 21 and the substrate 1 on the substrate stage 41, which have been brought close to each other, may contact each other. In this case, the air sensor 21 receives a large impact, so that the internal component of the air sensor 21 can be deformed or positionally shifted, and other components such as the substrate stage 41 can also be damaged. In order to bring the exposure apparatus 100 to an emergency stop, the operator may press an emergency stop button 14 (see FIG. 1) provided on the exposure apparatus 100.

To solve these problems, the measurement apparatus 20 according to this embodiment includes the first mode and the second mode as operation modes for the moving unit 22 to move the air sensor 21 in the +Z direction (the direction away from the surface of the substrate 1, to retract the air sensor 21. The first mode is the operation mode in which the moving unit 22 moves (retracts) the air sensor 21 in the +Z direction in accordance with reception of a normal retraction signal (first signal) instructing to retract the air sensor 21 when measurement by the air sensor 21 ends. The second mode is the operation mode in which the moving unit 22 moves (retracts) the air sensor 21 in the +Z direction in accordance with reception of an emergency retraction signal (second signal) instructing to retract the air sensor 21 in an emergency. The retraction time of the air sensor 21 is shorter in the second mode than in the first mode. The retraction time of the air sensor 21 means the time from reception of a retraction signal instructing to retract the air sensor 21 to the end of retraction of the air sensor 21. That is, the time from reception of an emergency retraction signal to the end of retraction of the air sensor 21 in the second mode is shorter than the time from reception of a normal retraction signal to the end of retraction of the air sensor 21 in the first mode. With this, it is possible to appropriately retract the air sensor 21 in accordance with the situation of the measurement apparatus 20. Here, the normal retraction signal and the emergency retraction signal are trigger signals (control signals) to be supplied from the controller CNT to the moving unit 22 to retract (that is, move in the +Z direction) the air sensor 21.

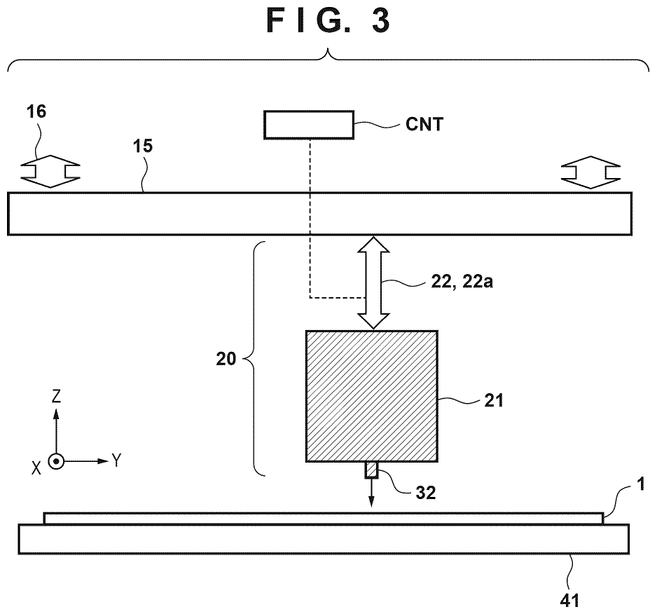

FIG. 3 schematically shows an example of the configuration of the measurement apparatus 20 according to this embodiment. As described above, the measurement apparatus 20 can include the air sensor 21 and the moving unit 22. The moving unit 22 in this embodiment includes one type of a moving mechanism 22a, and the air sensor 21 can be moved by the one type of the moving mechanism 22a in each of the first mode and the second mode. The moving mechanism 22a is attached to a frame 15 (support member). For example, the moving mechanism 22a includes an actuator including a stator provided to the frame 15 and a mover (movable element) provided to the air sensor 21. By moving the mover with respect to the stator, the air sensor 21 is moved in the ±Z directions. As the actuator of the moving mechanism 22a, an air cylinder, a linear motor, a voice coil motor, a solenoid, or the like can be used. Note that the frame 15 can be supported by the structure of the exposure apparatus 100 via a vibration damping mount 16.

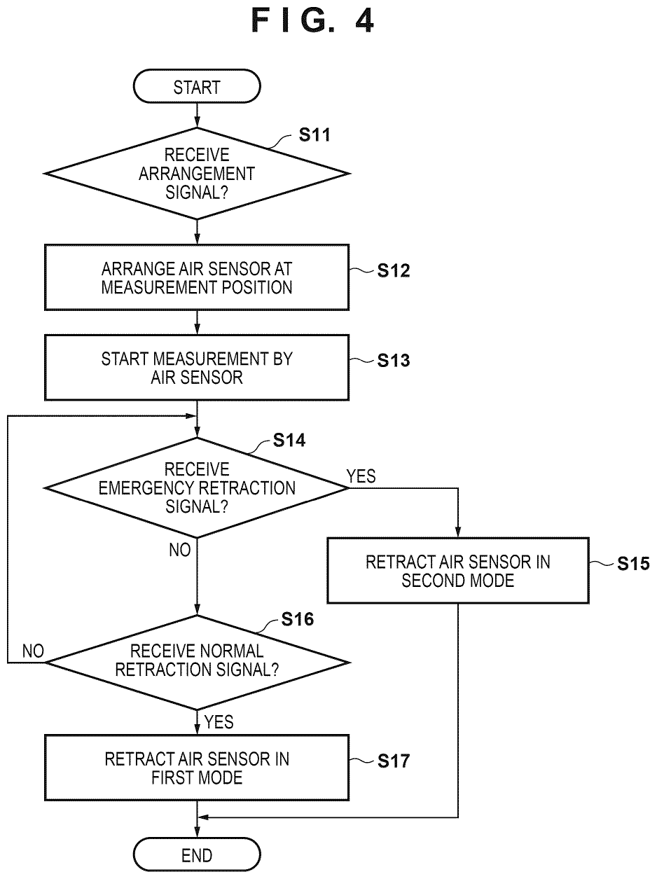

FIG. 4 is a flowchart illustrating the operation of the measurement apparatus 20 according to this embodiment. The flowchart of FIG. 4 illustrates the operation procedure of the measurement apparatus 20 under the control of the controller CNT. The flowchart of FIG. 4 is started in a state in which the air sensor 21 (measurement nozzle 32) is arranged at a retraction position. The retraction position is a position where the air sensor 21 is arranged farther from the substrate 1 in the +Z direction than a measurement position. The measurement position is a position where the air sensor 21 is arranged at a predetermined spacing from the surface of the substrate 1 to measure the surface height of the substrate 1.

If an arrangement signal is received in step S11, the measurement apparatus 20 advances to step S12, and moves the air sensor 21 (measurement nozzle 32) in the −Z direction by the moving unit 22 to arrange the air sensor 21 at the measurement position. The arrangement signal is a trigger signal (control signal) supplied from the controller CNT to the moving unit 22 to instruct to arrange the air sensor 21 (measurement nozzle 32) at the measurement position. Then, the measurement apparatus 20 advances to step S13, and starts measurement of the surface height of the substrate 1 by the air sensor 21 in accordance with reception of a measurement start signal. The measurement start signal is a trigger signal (control signal) supplied from the controller CNT to the air sensor 21 to instruct to start measurement of the surface height of the substrate 1.

During measurement of the surface height of the substrate 1, if an emergency retraction signal is received in step S14, the measurement apparatus 20 advances to step S15, and moves the air sensor 21 (measurement nozzle 32) in the +Z direction by the moving unit 22 in the second mode to arrange the air sensor 21 at the retraction position. When the air sensor 21 is arranged at the retraction position, retraction of the air sensor 21 ends. As described above, the emergency retraction signal is a trigger signal (control signal) supplied from the controller CNT to the moving unit 22 to instruct to retract the air sensor 21 in an emergency.

Here, in the exposure apparatus 100, an abnormality detection sensor that detects various kinds of abnormalities in the apparatus is provided. If the abnormality detection sensor detects an abnormality, the controller CNT can supply an emergency retraction signal to the moving unit 22. The various kinds of abnormalities are listed below. If the operator presses the emergency stop button 14, the controller CNT can also supply an emergency retraction signal to the moving unit 22.
an abnormality in the state of the exposure apparatus 100
an abnormality in the deviation, current, and/or position of the air sensor 21
an abnormality in the deviation, current, and/or position of the substrate stage 41
an abnormality in the deviation, current, and/or position of the frame
an abnormality in the deviation, current, and/or position of the vibration damping mount 16

If a normal retraction signal is received in step S16, the measurement apparatus 20 advances to step S17, and moves the air sensor 21 (measurement nozzle 32) in the +Z direction by the moving unit 22 in the first mode to arrange the air sensor 21 at the retraction position. When the air sensor 21 is arranged at the retraction position, retraction of the air sensor 21 ends. As described above, the normal retraction signal is a trigger signal (control signal) supplied from the controller CNT to the moving unit 22 to instruct to retract the air sensor 21 when measurement by the air sensor 21 ends. If the height information output from the air sensor 21 is acquired, the controller CNT can determine that measurement by the air sensor 21 ends, and supply the normal retraction signal to the moving unit 22.

Next, the first mode and the second mode for moving (retracting) the air sensor 21 in the +Z direction by the moving unit 22 will be described. As described above, the first mode is the operation mode in which the moving unit 22 moves (retracts) the air sensor 21 in the +Z direction when measurement by the air sensor 21 ends successfully. On the other hand, the second mode is the operation mode in which the moving unit 22 moves (retracts) the air sensor 21 in the +Z direction in an emergency, and the retraction time of the air sensor 21 is shorter than in the first mode.

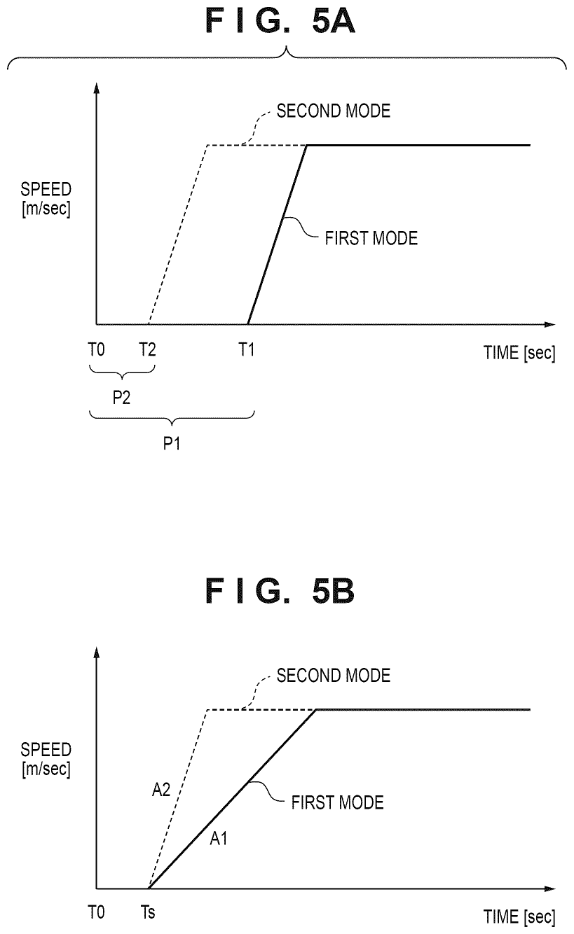

FIG. 5A shows an example of the temporal change of the moving speed of the air sensor 21 in each of the first mode and the second mode. In FIG. 5A, “T1” indicates a timing of starting to move the air sensor 21 by the moving unit 22 in the first mode. “T2” indicates a timing of starting to move the air sensor 21 by the moving unit 22 in the second mode. “T0” indicates a timing when the moving unit 22 receives a retraction signal (normal retraction signal or emergency retraction signal).

In the first mode, when a normal retraction signal is received at the timing T0, a predetermined preparation operation is performed before starting to move the air sensor 21 at the timing T1. On the other hand, in the second mode, when an emergency retraction signal is received at the timing T0, a predetermined preparation operation is omitted and the air sensor 21 is started to move at the timing T2. Accordingly, a waiting time P2 from reception of an emergency retraction signal to the start of movement of the air sensor 21 in the second mode can be made shorter than a waiting time P1 from reception of a normal retraction signal to the start of movement of the air sensor 21 in the first mode. Therefore, the retraction time of the air sensor 21 in the second mode can be made shorter than the retraction time of the air sensor 21 in the first mode.

FIG. 5B shows an example of the temporal change of the moving speed of the air sensor 21 in each of the first mode and the second mode. In FIG. 5B, “Ts” indicates a timing of starting to move the air sensor 21 by the moving unit 22 in each of the first mode and the second mode. “T0” indicates a timing when the moving unit 22 receives a retraction signal (normal retraction signal or emergency retraction signal).

In the first mode, when a normal retraction signal is received at the timing T0, the air sensor 21 is started to move at the timing Ts, and the air sensor 21 is moved at an acceleration A1. On the other hand, in the second mode, when an emergency retraction signal is received at the timing T0, the air sensor 21 is started to move at the timing Ts, and the air sensor 21 is moved at an acceleration A2 higher than the acceleration A1. This can make the retraction time of the air sensor 21 in the second mode shorter than the retraction time of the air sensor 21 in the first mode. Here, in the second mode, making the waiting time shorter than in the first mode as shown in FIG. 5A and making the acceleration higher than in the first mode as shown in FIG. 5B may be used in combination.

As described above, the measurement apparatus 20 according to this embodiment includes the first mode in which the moving unit 22 moves (retracts) the air sensor 21 in accordance with reception of a normal retraction signal, and the second mode in which the moving unit 22 moves (retracts) the air sensor 21 in accordance with reception of an emergency retraction signal. The retraction time of the air sensor 21 is shorter in the second mode than in the first mode. Thus, it is possible to appropriately retract the air sensor 21 in accordance with the situation of the measurement apparatus 20.

Here, in the embodiment described above, the air sensor 21 using a gas is exemplified as the sensor moved by the moving unit 22 in each of the first mode and the second mode. However, the sensor moved by the moving unit 22 may be any sensor as long as it includes a facing portion to face a measurement target surface and measures the position of the measurement target surface in a state in which the facing portion is arranged at a predetermined spacing from the measurement target surface. For example, an optical sensor or a capacitive sensor may be used as the sensor moved by the moving unit 22.

### Second Embodiment

The second embodiment according to the present disclosure will be described. In this embodiment, an example will be described in which a plurality of types of moving mechanisms different from each other in a method of moving an air sensor 21 are provided in a moving unit 22. Note that this embodiment basically takes over the first embodiment, and matters not mentioned below can follow the first embodiment.

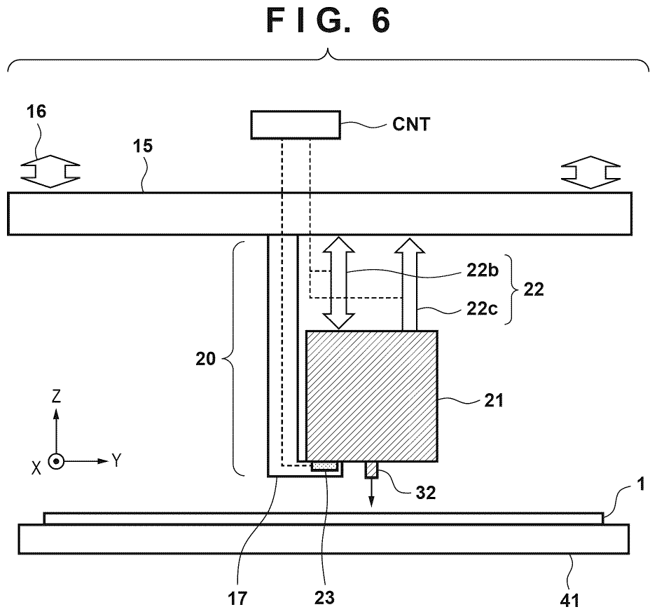

FIG. 6 schematically shows an example of the configuration of a measurement apparatus 20 according to this embodiment. In the measurement apparatus 20 according to this embodiment, a first moving mechanism 22b and a second moving mechanism 22c different from each other in a method of moving the air sensor 21 are provided in the moving unit 22. The air sensor 21 is moved using the first moving mechanism and the second moving mechanism in each of the first mode and the second mode. The first moving mechanism 22b includes an actuator including a stator and a mover, and moves the air sensor 21 in the ±Z directions by moving the mover with respect to the stator. As the actuator of the first moving mechanism 22b, an air cylinder, a linear motor, a voice coil motor, a solenoid, or the like can be used. The second moving mechanism 22c can include a spring member that applies a force in the +Z direction to the air sensor 21 (measurement nozzle 32) arranged at a predetermined spacing from the surface of a substrate 1.

The measurement apparatus 20 according to this embodiment can further include a fixing mechanism 23 that fixes the position of the air sensor 21 arranged at a predetermined spacing from the surface of the substrate 1 to measure the surface height of the substrate 1, that is, the position of the air sensor 21 arranged at the measurement position. For example, the fixing mechanism 23 is provided on a support member 17 attached to a frame 15, and fixes the position of the air sensor 21 (measurement nozzle 32) by using at least one of a vacuum suction force and an electromagnetic force. As the fixing mechanism 23, a vacuum chuck, an electromagnet, a electrostatic chuck, a voice coil motor, a solenoid, or the like can be used.

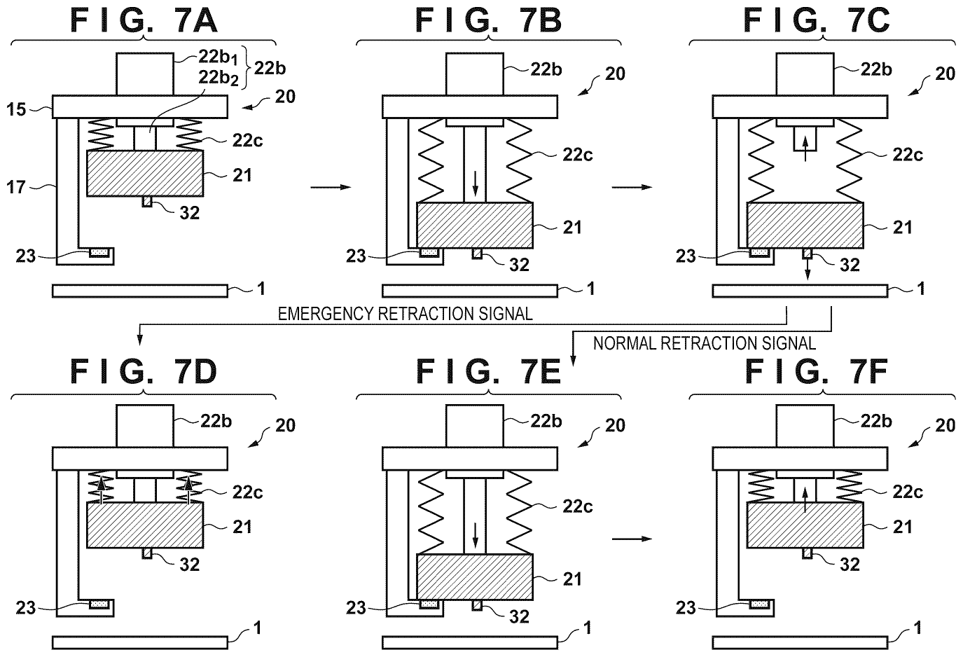

FIGS. 7A to 7F schematically show a specific example of the configuration and operation of the measurement apparatus 20 according to this embodiment. In the measurement apparatus 20 according to this embodiment, the first moving mechanism 22b includes an actuator including a stator 22b₁ provided on the frame 15, and a mover 22b₂ movable in the ±Z directions with respect to the stator 22b₁. The mover 22b₂ of the first moving mechanism 22b can contact the upper surface of the air sensor 21. The second moving mechanism 22c includes a spring member with one end connected to the frame 15 and the other end connected to the air sensor 21. By using the spring member for the second moving mechanism 22c, complicated control is not required, and the measurement apparatus 20 can have a simple configuration. Note that in the following description, the first moving mechanism 22b may be referred to as the “actuator 22b”, and the second moving mechanism 22c may be referred to as the “spring member 22c”.

The measurement apparatus 20 according to this embodiment can operate according to the flowchart of FIG. 4 described above. FIG. 7A shows a state of the measurement apparatus 20 before the flowchart of FIG. 4 starts, that is, a state in which the air sensor 21 is arranged at a retraction position. If an arrangement signal is received in step S11, the measurement apparatus 20 advances to step S12, and moves the air sensor 21 in the −Z direction by moving the mover 22b₂ of the actuator 22b in the −Z direction as shown in FIG. 7B. When the air sensor 21 is arranged at the measurement position, the fixing mechanism 23 fixes the position of the air sensor 21.

Then, as shown in FIG. 7C, the measurement apparatus 20 moves the mover 22b₂ of the actuator in the +Z direction to separate the mover 22b₂ from the air sensor 21. In this state in which the mover 22b₂ is separated from the air sensor 21 (the separation state or the second state), a force in the +Z direction due to the restoring force of the spring member 22c is applied to the air sensor 21. However, since the position of the air sensor 21 is fixed by the fixing mechanism 23, the air sensor 21 remains arranged at the measurement position. In this state, the measurement apparatus 20 advances to step S13, and starts measurement of the surface height of the substrate 1 by the air sensor 21 in accordance with reception of a measurement start signal.

During measurement of the surface height of the substrate 1, if an emergency retraction signal is received in step S14, the measurement apparatus 20 advances to step S15, and moves the air sensor 21 in the +Z direction in the second mode to arrange the air sensor 21 at the retraction position. More specifically, as shown in FIG. 7D, the measurement apparatus 20 releases fixing of the position of the air sensor 21 by the fixing mechanism 23 to allow the air sensor 21 to move in the +Z direction by the force of the spring member 22c, thereby arranging the air sensor 21 at the retraction position. That is, in the second mode in this embodiment, by releasing fixing of the position of the air sensor 21 by the fixing mechanism 23 in the separation state, the air sensor 21 is moved in the +Z direction by the force of the spring member 22c, thereby being arranged at the retraction position.

After measurement of the surface height of the substrate 1 ends and if a normal retraction signal is received in step S16, the measurement apparatus 20 advances to step S17, and moves the air sensor 21 in the +Z direction in the first mode to arrange the air sensor 21 at the retraction position. More specifically, as shown in FIG. 7E, the measurement apparatus 20 moves the mover 22b₂ of the actuator 22b in the −Z direction to bring the mover 22b₂ into contact with the air sensor 21, and in this state, releases fixing of the position of the air sensor 21 by the fixing mechanism 23. This operation of moving the mover 22b₂ in the −Z direction to bring it into contact with the air sensor 21 corresponds to the preparation operation described with reference to FIG. 5A. Then, as shown in FIG. 7F, the measurement apparatus 20 moves the mover 22b₂ of the actuator 22b in the +Z direction, thereby moving the air sensor 21 in the +Z direction by the force of the spring member 22c while supporting the air sensor 21 by the mover 22b₂. Thus, the air sensor 21 is arranged at the retraction position.

In this manner, in the first mode, if a normal retraction signal is received, the air sensor 21 is started to move after performing the preparation operation of moving the mover 22b₂ in the −Z direction to bring it into contact with the air sensor 21. On the other hand, in the second mode, if an emergency retraction signal is received, the preparation operation is omitted and the air sensor 21 is started to move. Accordingly, a waiting time P2 from reception of an emergency retraction signal to the start of movement of the air sensor 21 in the second mode can be made shorter than a waiting time P1 from reception of a normal retraction signal to the start of movement of the air sensor 21 in the first mode. Therefore, the retraction time of the air sensor 21 in the second mode can be made shorter than the retraction time of the air sensor 21 in the first mode.

In the first mode, the mover 22b₂ is moved in the +Z direction while supporting the air sensor 21 by the mover 22b₂ of the actuator 22b, thereby moving the air sensor 21 in the +Z direction by the force of the spring member 22c. On the other hand, in the second mode, without being supported by the mover 22b₂ of the actuator 22b, the air sensor 21 is moved in the +Z direction only by the force of the spring member 22c. With this, an acceleration A2 in moving the air sensor 21 in the second mode can be made higher than an acceleration A1 in moving the air sensor 21 in the first mode. Therefore, the retraction time of the air sensor 21 in the second mode can be made shorter than the retraction time of the air sensor 21 in the first mode.

### Third Embodiment

The third embodiment according to the present disclosure will be described. In this embodiment, an example will be described in which only a part (measurement nozzle 32) of an air sensor 21 is moved by a moving unit 22. That is, this embodiment describes that a measurement apparatus 20 may be configured to move at least the facing portion (measurement nozzle 32) of the air sensor 21 by the moving unit 22. Note that this embodiment basically takes over the first embodiment, and matters not mentioned below can follow the first embodiment. The second embodiment may be applied to this embodiment, and an example applied with the configuration of the second embodiment will be described below.

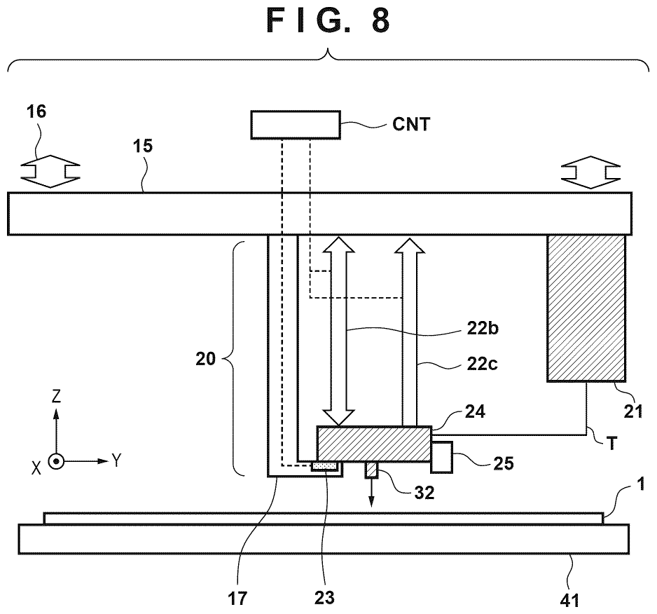

FIG. 8 schematically shows an example of the configuration of the measurement apparatus 20 according to this embodiment. The measurement apparatus 20 according to this embodiment can be configured to move, by the moving unit 22 (a first moving mechanism 22b and a second moving mechanism 22c), only the measurement nozzle 32 serving as the facing portion of the air sensor 21 which faces the surface of a substrate 1. More specifically, the measurement nozzle 32 of the air sensor 21 is provided in a holder 24, and the moving unit 22 moves the measurement nozzle 32 in the ±Z directions by moving the holder 24 in the ±Z directions. The components of the air sensor 21 other than the measurement nozzle 32 are supported by a frame 15, and air is supplied to the measurement nozzle 32 via a pipe T. When the measurement apparatus 20 is configured in this manner, the weight of the object moved by the moving unit 22 decreases, so that the acceleration in moving the object in the second mode can further be increased.

Here, in the measurement apparatus 20 according to this embodiment, since there is a margin for the weight of the object moved by the moving unit 22, the moving unit 22 can also move another component. For example, the measurement apparatus 20 can move, by the moving unit 22, a sensor that measures the surface height of the substrate 1 using a method different from the air sensor 21. In FIG. 8, an optical sensor 25 (second sensor) that measures the surface height of the substrate 1 using light is provided on the holder 24. The optical sensor 25 is a measuring device that emits light to the surface of the substrate 1 and receives reflected light from the substrate 1, thereby measuring the surface height of the substrate 1 based on the reflected light. The moving unit 22 moves the holder 24 in the ±Z directions, thereby moving the optical sensor 25 in the ±Z directions together with the measurement nozzle 32 of the air sensor 21.

### Embodiment of Article Manufacturing Method

An article manufacturing method according to an embodiment of the present disclosure is suitable for manufacturing an article, for example, a microdevice such as a semiconductor device or an element having a microstructure. The article manufacturing method according to this embodiment includes a forming step of forming a pattern on a substrate by using a lithography apparatus (lithography method) described above, a processing step of processing the substrate with the pattern formed in the forming step, and a manufacturing step of manufacturing an article from the substrate processed in the processing step. When the lithography apparatus is constituted as an exposure apparatus, the forming step can be a step of forming a latent image pattern in a photosensitive agent applied on a substrate by exposing the substrate by using the exposure apparatus (exposure method) described above. In this case, the processing step can include a step of developing the substrate on which the latent image pattern is formed. The article manufacturing method further includes other known steps (oxidation, deposition, vapor deposition, doping, planarization, etching, resist removal, dicing, bonding, packaging, and the like). The article manufacturing method of this embodiment is more advantageous than conventional methods in at least one of the performance, quality, productivity, and production cost of the article.

### Other Embodiments

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-031940, filed on Feb. 28, 2025, which is hereby incorporated by reference herein in its entirety.

What is claimed is:

1. A measurement apparatus that measures a position of a measurement target surface, comprising:
a sensor including a facing portion which faces the measurement target surface, and configured to measure a position of the measurement target surface in a first state in which the facing portion is arranged at a predetermined spacing from the measurement target surface; and
a moving unit configured to move at least the facing portion of the sensor,
wherein the moving unit operates in a first mode for moving the facing portion in a direction away from the measurement target surface in accordance with reception of a first signal instructing to retract the facing portion when measurement by the sensor ends, and a second mode for moving the facing portion in the direction in accordance with reception of a second signal instructing to retract the facing portion in an emergency, and
wherein a time from reception of the second signal to an end of retraction of the facing portion in the second mode is shorter than a time from reception of the first signal to an end of retraction of the facing portion in the first mode.

2. The apparatus according to claim 1, wherein
a time from reception of the second signal to a start of movement of the facing portion in the second mode is shorter than a time from reception of the first signal to a start of movement of the facing portion in the first mode.

3. The apparatus according to claim 1, wherein
an acceleration in moving the facing portion is higher in the second mode than in the first mode.

4. The apparatus according to claim 1, wherein
the moving unit includes a first moving mechanism and a second moving mechanism different from each other in a method of moving the facing portion, and
the facing portion is moved using the first moving mechanism and the second moving mechanism in each of the first mode and the second mode.

5. The apparatus according to claim 4, wherein
the first moving mechanism includes an actuator including a mover movable in the direction, and
the second moving mechanism includes a spring member configured to apply a force in the direction to the facing portion in the first state.

6. The apparatus according to claim 5, wherein
during measurement by the sensor, the mover is arranged to be separated from the facing portion,
in the first mode, the moving unit brings the mover into contact with the facing portion, and moves the facing portion in the direction by the force of the spring member while supporting the facing portion by the mover, and
in the second mode, in a second state in which the mover is separated from the facing portion, the moving unit moves the facing portion in the direction by the force of the spring member.

7. The apparatus according to claim 6, further comprising a fixing mechanism configured to fix a position of the facing portion in the first state,
wherein in the second mode, the moving unit releases fixing of a position the facing portion by the fixing mechanism, thereby moving the facing portion in the direction by the spring member.

8. The apparatus according to claim 7, wherein
the fixing mechanism fixes a position of the facing portion by using at least one of a vacuum suction force and an electromagnetic force.

9. The apparatus according to claim 1, wherein
the moving unit includes one type of a moving mechanism, and the facing portion is moved using the one type of a moving mechanism in each of the first mode and the second mode.

10. The apparatus according to claim 1, wherein
the sensor includes, as the facing portion, a nozzle configured to discharge gas toward the measurement target surface through a conduit, and measures a height of the measurement target surface based on a pressure in the conduit.

11. The apparatus according to claim 1, further comprising a second sensor configured to measure a position of the measurement target surface by using light,
wherein the moving unit moves the second sensor in the direction together with the facing portion.

12. A positioning apparatus that positions a substrate, comprising:
a stage configured to move while holding the substrate;
a measurement apparatus defined in claim 1, and configured to measure a position of a surface of the substrate as a measurement target surface; and
a controller configured to control the stage based on a measurement result of the measurement apparatus.

13. A lithography apparatus that forms a pattern on a substrate, comprising
a positioning apparatus defined in claim 12.

14. An article manufacturing method comprising:
forming a pattern on a substrate by using a lithography apparatus defined in claim 13;
processing the substrate having undergone the forming; and
manufacturing an article from the substrate having undergone the processing.
